(19) United States
(12) Patent Application Publication
(10) Pub. No.: US 2025/0362875 A1
(43) Pub. Date: Nov. 27, 2025

(54) COMPUTE-IN-MEMORY DEVICES AND METHODS OF OPERATING THE SAME

(71) Applicant: Taiwan Semiconductor Manufacturing Company, Ltd., Hsinchu (TW)

(72) Inventors: Wei-Chang Zhao, Hsinchu City (TW); Haruki Mori, Hsinchu City (TW); Hidehiro Fujiwara, Hsinchu City (TW)

(73) Assignee: Taiwan Semiconductor Manufacturing Company, Ltd., Hsinchu (TW)

(21) Appl. No.: 19/292,341

(22) Filed: Aug. 6, 2025

Related U.S. Application Data
(63) Continuation of application No. 17/827,223, filed on May 27, 2022.
(60) Provisional application No. 63/283,018, filed on Nov. 24, 2021.

(51) Int. Cl. G06F 7/544; G06F 7/501; G06F 7/523; H03K 19/20

(52) U.S. Cl. CPC G06F 7/5443; G06F 7/501; G06F 7/523; H03K 19/20

(57) ABSTRACT

An integrated circuit includes a first logic gate configured to receive a first input signal and a second input signal, and generate a first control signal based on a first bit of first input signal and a first bit of the second input signal obtained in a current cycle. The integrated circuit includes a first backup storage component configured to store a second bit of the first input signal and a second bit of the second input signal obtained in a previous cycle. The integrated circuit includes a plurality of first macros each configured to selectively compute, based on the first control signal, a first multiply-accumulate (MAC) value for the first bit of the first input signal and the first bit of the second input signal.

### CROSS-REFERENCE TO RELATED APPLICATION

This application is a continuation of U.S. patent application Ser. No. 17/827,223, filed May 27, 2022, which claims priority to and the benefit of U.S. Provisional Application No. 63/283,018, filed Nov. 24, 2021, each of which is incorporated herein by reference in its entirety for all purposes.

### BACKGROUND

With advances in modern day semiconductor manufacturing processes and the continually increasing amounts of data generated each day, there is an ever greater need to store and process large amounts of data, and therefore a motivation to find improved ways of storing and processing large amounts of data. Although it is possible to process large quantities of data in software using conventional computer hardware, existing computer hardware can be inefficient for some data-processing applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example neural network, in accordance with some embodiments.

FIG. 2 illustrates a block diagram of a Compute-in-Memory system, in accordance with some embodiments.

FIG. 3 illustrates a schematic diagram of one of the macros of the Compute-in-Memory system shown in FIG. 2, in accordance with some embodiments.

FIG. 4 illustrates a flow chart of an example method to operate the Compute-in-Memory system of FIG. 2, in accordance with some embodiments.

FIGS. 5, 6, 7, 8, and 9 illustrate an example of how the macro of the Compute-in-Memory system shown in FIG. 2 operates to efficiently output a MAC value, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this regard, machine learning has emerged as an effective way to analyze and derive value from such large quantities of data. Generally, machine learning is a field of computer science that involves algorithms that allow computers to “learn” (e.g., improve performance of a task) without being explicitly programmed. Machine learning can involve different techniques for analyzing data to improve upon a task. One such technique (such as deep learning) is based on neural networks. However, machine learning performed on conventional computer systems can involve excessive data transfers between memory and the processor, leading to high power consumption and slow compute times.

Compute-in-Memory (CiM) (which can also be referred to as in-memory processing) involves performing compute operations within a memory array. Stated another way, compute operations are performed directly on the data read from the memory cells instead of transferring the data to a digital processor for processing. By avoiding transferring some data to the digital processor, the bandwidth limitations associated with transferring data back and forth between the processor and memory in a conventional computer system are reduced.

One application for such a CiM is artificial intelligence (AI), and specifically machine learning. For example, a computing system (e.g., a CiM system) can use multiple layers of computational nodes, where lower layers perform computations based on results of computations performed by higher layers. These computations sometimes may rely on the computation of dot-products and absolute difference of vectors, typically computed with MAC (operations) performed on the parameters, input data and weights. The term “MAC” can refer to multiply-accumulate, multiplication/accumulation, or multiplier accumulator, in general referring to an operation that includes the multiplication of two values, and the accumulation of a sequence of multiplications.

The present disclosure provides various embodiments of a CiM system that can efficiently output a number of MAC values on a number of input signals. For example, the CiM system, as disclosed herein, can include a number of macros formed as an array, and a control circuit operatively coupled to the array. Each macro can output a number of MAC values of a first input signal and a second input signal. Each of the first and second input signals can include a respective plural number of (e.g., binary) bits. The macro can compute or otherwise determine a MAC value on a first one of the bits of the first input signal and a first one of the bits of the second input signal obtained in a current cycle. Further, the macro can determine the MAC value in the current cycle as either a fixed logic value or being computed based on the respective first bits obtained in the current cycle. In various embodiments, prior to computing the MAC value (of the respective first bits), the control circuit can output a control signal to the macro based on the first bits, and the macro can determine whether there is a need to toggle its inputs to the first bits. As such, as a frequency of the cycles increases (e.g., thereby computing the MAC values in a higher frequency), the macro can significantly decrease an amount of toggling to bits of the input signals, which can advantageously reduce power consumption of the whole CiM system while maintaining the high speed computation.

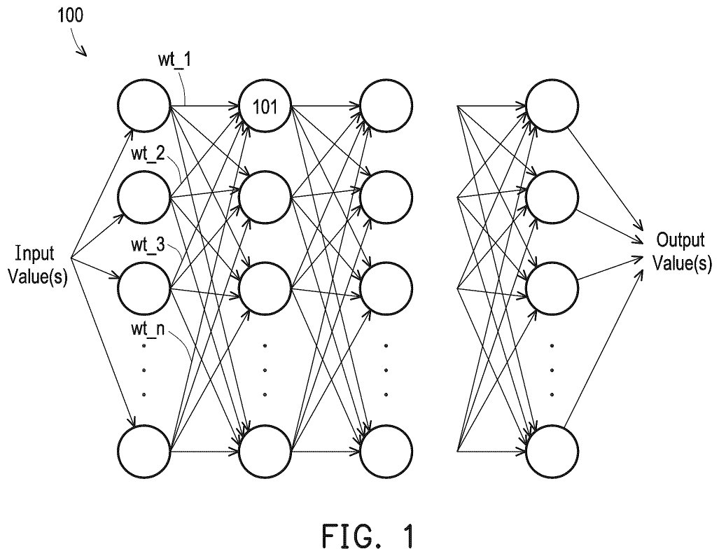

FIG. 1 depicts an exemplary neural network 100, in accordance with various embodiments. As shown, the inner layers of a neural network can largely be viewed as layers of neurons that each receive weighted outputs from the neurons of other (e.g., preceding) layer(s) of neurons in a mesh-like interconnection structure between layers. The weight of the connection from the output of a particular preceding neuron to the input of another subsequent neuron is set according to the influence or effect that the preceding neuron is to have on the subsequent neuron (for simplicity, only one neuron 101 and the weights of input connections are labeled). Here, the output value of the preceding neuron is multiplied by the weight of its connection to the subsequent neuron to determine the particular stimulus that the preceding neuron presents to the subsequent neuron.

A neuron's total input stimulus corresponds to the combined stimulation of all of its weighted input connections. According to various implementations, if a neuron's total input stimulus exceeds some threshold, the neuron is triggered to perform some, e.g., linear or non-linear mathematical function on its input stimulus. The output of the mathematical function corresponds to the output of the neuron which is subsequently multiplied by the respective weights of the neuron's output connections to its following neurons.

Generally, the more connections between neurons, the more neurons per layer and/or the more layers of neurons, the greater the intelligence the network is capable of achieving. As such, neural networks for actual, real-world artificial intelligence applications are generally characterized by large numbers of neurons and large numbers of connections between neurons. Extremely large numbers of calculations (not only for neuron output functions but also weighted connections) are therefore involved in processing information through a neural network.

As mentioned above, although a neural network can be completely implemented in software as program code instructions that are executed on one or more traditional general purpose central processing unit (CPU) or graphics processing unit (GPU) processing cores, the read/write activity between the CPU/GPU core(s) and system memory that is needed to perform all the calculations is extremely intensive. The overhead and energy associated with repeatedly moving large amounts of read data from system memory, processing that data by the CPU/GPU cores and then writing resultants back to system memory, across the many millions or billions of computations needed to effect the neural network have not been entirely satisfactory in many aspects.

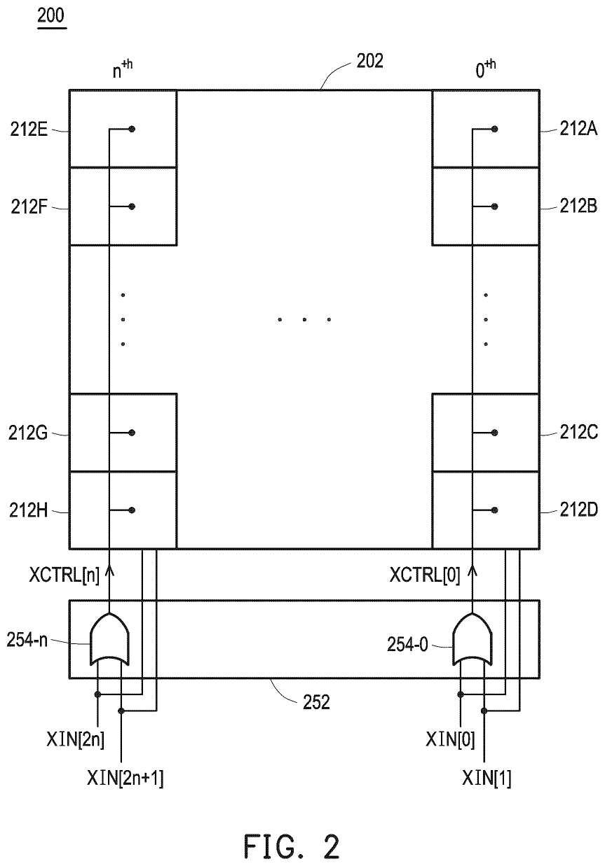

FIG. 2 illustrates a block diagram of an integrated circuit (e.g., a CiM system) 200 that can efficiently output a number of MAC values on a number of input signals, in accordance with various embodiments. It should be understood that the CiM system 200 of FIG. 2 is simplified for illustration purposes. Thus, the CiM system 200 can include any of various other components, while remaining within the scope of present disclosure. For example, the CiM system 200 may include one or more other control circuits or processing units configured to send a command to the components shown in FIG. 2 to perform a number of MAC operations on a number of input signals, respectively.

As shown, the CiM system 200 includes a CiM array 202 and a control circuit 252, in accordance with various embodiments. The CiM array 202 includes a number of (e.g., CiM) macros: 212A, 212B, 212C, 212D, 212E, 212F, 212G, and 212H. Although eight macros are shown, it should be understood that the CiM array 202 can include any number of macros while remaining within the scope of present disclosure. These macros of the CiM array 202 are sometimes collectively referred to as macros 212. In some embodiments, the macros 212 can be arranged across multiple columns and rows. For example in FIG. 2, the macros 212A to 212D can be arranged in a first one of the columns (e.g., 0^{th} column), while each of these macros are arranged in a respective row. Similarly, the macros 212E to 212H can be arranged in a second, different one of the columns (e.g., n^{th} column), while each of these macros are arranged in a respective row.

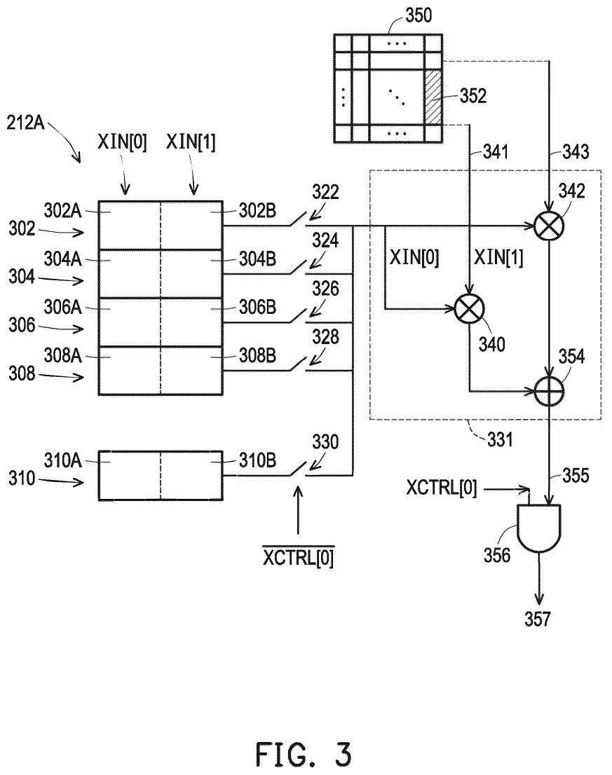

As will be discussed in further detail with respect to FIG. 3, each of the macros 212 can output a number of MAC values for a first input signal and a second input signal based on a respective control signal whose logic value is determined based on the first and second input signals. In various embodiments, the macros disposed in the same column can receive the same (first and second) input signals to output respective MAC values, either in parallel or in sequence. Alternatively stated, the macros in the same column can receive the same control signal (determined based on the same input signals) to output a number of MAC values, which may be presented (e.g., outputted) in respectively different rows. For example in FIG. 2, the macros 212A to 212D (disposed in the 0^{th} column) can each receive input signals, XIN[0] and XIN[1], and output a MAC value for the input signals, XIN[0] and XIN[1], based on a control signal, XCTRL[0]; and the macros 212E to 212H (disposed in the nth column) can each receive input signals, XIN[2n] and XIN[2n+1], and output a MAC value for the input signals, XIN[2n] and XIN[2n+1], based on a control signal, XCTRL[n].

In some embodiments, the control circuit 252 includes a number of logic gates that each can generate the control signal for a respective column of the CiM array 202. For example in FIG. 2, the control circuit 252 includes OR gates 254-0 and 254-n. The OR gate 254-0 can generate the control signal XCTRL[0] through performing an OR operation on the input signals XIN[0] and XIN[1] and output the control signal XTRL[0] to each of the macros disposed in the 0^{th} column; and the OR gate 254-n can generate the control signal XCTRL[n] through performing an OR operation on the input signals XIN[2n] and XIN[2n+1] and output the control signal XTRL[n] to each of the macros disposed in the nth column.

Referring to FIG. 3, one of the macros 212 (212A as a representative example) is shown in further detail. As shown, the macro 212A includes a number of input storage components 302, 304, 306, 308, and includes or is coupled to one backup storage component 310. For example, each of the macros 212 may include a respective backup storage component 310, or the macros 212 disposed along the same column (e.g., 212A to 212D) may share a common backup storage component 310. Each of the input/backup storage components may be implemented as a register memory in some of the embodiments, but it should be understood that the input/backup storage components can include any of various other suitable memory components while remaining within the scope of present disclosure.

The storage components 302 to 310 can each store at least two respective bits of a first input signal and a second input signal. The input storage components 302 to 308 are configured to store respective bits of the first and second input signals received or otherwise obtained for a current CiM operation, while the backup storage component 310 is configured to store two (e.g., last computed) bits of the first and second input signals received or otherwise obtained for a previous CiM operation. Further, the storage component 302 may correspond to respective most significant bits (MSB) of the first and second input signals obtained in the current CiM operation, while the storage component 308 may correspond to respective least significant bits (LSB) of the first and second input signals obtained in the current CiM operation.

Within each CiM operation, the macro 212A may perform a MAC operation on the bits stored in each of the input storage components 302 to 308 during a respective one of a number of different cycles. The macro 212A can sequentially perform the MAC operations according to a value of the bits of the first and second input signals, in some embodiments. For example, the macro 212A can perform a first MAC operation on the respective MSBs of the first and second input signals (stored in 302A and 302B of the input storage component 302, respectively) in a first cycle; a second MAC operation on the respective next MSBs of the first and second input signals (stored in 304A and 304B of the input storage component 304, respectively) in a second cycle; a third MAC operation on the respective next LSBs of the first and second input signals (stored in 306A and 306B of the input storage component 306, respectively) in a third cycle; and a fourth MAC operation on the respective LSBs of the first and second input signals (stored in 308A and 308B of the input storage component 308, respectively) in a fourth cycle. Accordingly, the backup storage component 310 may store, in 310A and 310B, respectively, the LSBs of the first and second input signals obtained in the previous CiM operation.

However, it should be understood that the macro 212A can sequentially perform the MAC operations in a different order, while remaining within the scope of present disclosure. For example, the macro 212A can perform the MAC operations starting with the LSBs of the first and second input signals (in the current CiM operation). In such a scenario, the backup storage component 310 may store the MSBs of the first and second input signals in the previous CiM operation. Additionally, the macro 212A can “selectively” perform each of the MAC operations based on a control signal, which will be discussed in further detail below.

The macro 212A further includes a number of switches 322, 324, 326, 328, and 330. The switches 322 to 330 are coupled to the input/backup storage components 302 to 310, respectively. Further, in each cycle, only one of the switches 322 to 330 can be turned on to toggle or otherwise couple the corresponding storage component to a MAC computation unit 331 of the macro 212A. In accordance with various embodiments, the switches 322 to 328 may be sequentially turned on in respective cycles, unless the switch 330 is turned on. The switch 330 can be turned on based on the control signal, XTRL[0], specifically, a logic inverse value of the control signal, XTRL[0].

As discussed with respect to FIG. 2, the control signal, XTRL[0], is generated by OR'ing respective bits of the input signals, XIN[0] and XIN[1], obtained in a current cycle. For example, in a cycle, if the bits of the input signals, XIN[0] and XIN[1], are each obtained as a logic 0, then X̅T̅R̅L̅[̅0̅]̅ is equal to a logic 1, which can turn on the switch 330 (with the switches 322 to 328 remaining turned off), thereby coupling the storage component 310 to the MAC computation unit 331. Otherwise (e.g., at least one of the bits of the input signals, XIN[0] and XIN[1], is not equal to a logic 0), X̅T̅R̅L̅[̅0̅]̅ remains to be a logic 0. Thus, the switches 322 to 328 can be sequentially turned on in the original order of accessing the storage components 302 to 308 (e.g., from the MSBs to LSBs, or from the LSBs to the MSBs).

The macro 212A further includes at least a first multiplier 340, a second multiplier 342, and an adder 354, which can form the MAC computation unit 331. The first multiplier 340 and second multiplier 342 are each configured to multiple a bit of one of the first or second input signals (e.g., obtained in a current cycle) by a respective weight. In some embodiments, the first multiplier 340 can retrieve one of the bits of the input signal, XIN[0], upon the corresponding switch being turned on, and multiple the retrieved bit by a weight 341; and the second multiplier 342 can retrieve one of the bits of the input signal, XIN[1], upon the corresponding switch being turned on, and multiple the retrieved bit by a weight 343. Next, the adder 354 can sum the multiplication results provided by the multipliers 340 and 342, and output the sum as an intermediate MAC value 355.

For example, in response to the switch 322 being turned on, 302A and 302B of the storage components 302 can be coupled to the multipliers 340 and 342, respectively. Next, the multiplier 340 can multiple the bit obtained from 302A by the weight 341, and the multiplier 342 can multiple the bit obtained from 302B by the weight 341. The adder 354 can then sum the multiplied bits as the intermediate MAC value 355 in the current cycle. On the other hand (where the switch 322 is not turned on as originally scheduled, and in turn, the switch 330 is turned on), the macro 212A can skip the MAC operation in this cycle and output a final MAC value 357 as a fixed logic value.

The macro 212A can store the weights 341 and 343 in respectively different memory (or bit) cells 352 of a coupled memory array 350. Although in the illustrated embodiment of FIG. 3, each macro has a respective memory array, it should be understood that the macros 212 of the CiM array 202 can share a single memory array, where each macro is operatively coupled to a respective portion of the shared memory array. The memory array 350 can be implemented as any of various suitable memory arrays, in accordance with various embodiments. Example memory arrays 350 include, but are not limited to, a static random access memory (SRAM) array, a flash memory array, a phase change memory (PCM) array, a resistive random access memory (RRAM) array, a dynamic random access memory (DRAM) array, and a magnetoresistive random access memory (MRAM) array. Each of the memory cells 352 of the memory array 350 can store a (e.g., logic) value corresponding to a weight. In the applications of neural networks, such a weight is sometimes referred to as a synapse between neurons.

Operatively coupled to the MAC computation unit 331, the macro 212A further includes a logic gate 356 (e.g., an AND gate) configured to receive the intermediate MAC value 355 (regardless of being computed or not) and the control signal, XTRL[0], as inputs, and to perform an AND operation on these two inputs to output the final MAC value 357. As discussed above, a logic value of the control signal XTRL[0] is determined by OR'ing the bits of the input signals, XIN[0] and XIN[1], in a certain cycle. For example, if the bits are each equal to a logic 0, the control signal XTRL[0] is equal to a logic 0, which can cause a final MAC value 357 to be a logic 0 regardless of the intermediate MAC value 355. Alternatively stated, the macro 212A can determine or otherwise identify the bits of the first and second input signals in a certain cycle based on the control signal, XTRL[0]. If both of the bits are logic 0s, the macro 212A can skip toggling the corresponding switch (one of the switches 322 to 328) and performing the MAC operation to directly output the final MAC value as a fixed logic 0.

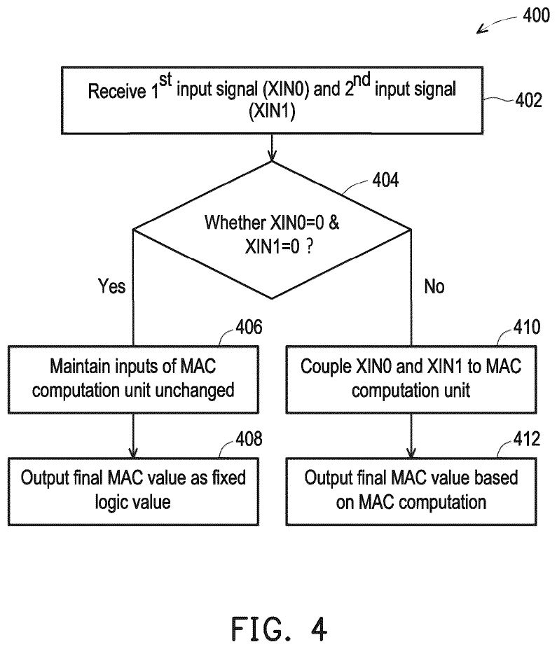

FIG. 4 illustrates a flowchart of an example method 400 of operating a CiM system (e.g., 200), in accordance with some embodiments. The method 400 may be used to reduce a computation amount of the CiM system based on identifying logic values of bits of the input signals obtained in each cycle, and skipping a corresponding MAC operation when identifying a certain combination of the logic values of the bits. It is noted that the method 400 is merely an example and is not intended to limit the present disclosure. Accordingly, it is understood that additional operations may be provided before, during, and after the method 400 of FIG. 4, and that some other operations may only be briefly described herein.

In brief overview, the method 400 starts with operation 402 of receiving a first input signal (e.g., XIN[0]) and a second input signal (e.g., XIN[1]). The method 400 proceeds to operation 404 of determining whether respective bits of the first and second inputs signals are each equal to a logic 0. In response to determining that the bits are both equal to logic 0s, the method 400 continues to operation 406 of maintaining inputs of a MAC computation unit unchanged. Next, the method 400 continues to operation 408 of outputting a final MAC value as a fixed logic value. In response to determining that at least one of the bits is not equal to a logic 0, the method 400 continues to operation 410 of coupling the bits of the input signals to the MAC computation unit. Next, the method 400 continues to operation 412 of outputting the final MAC value based on MAC computation.

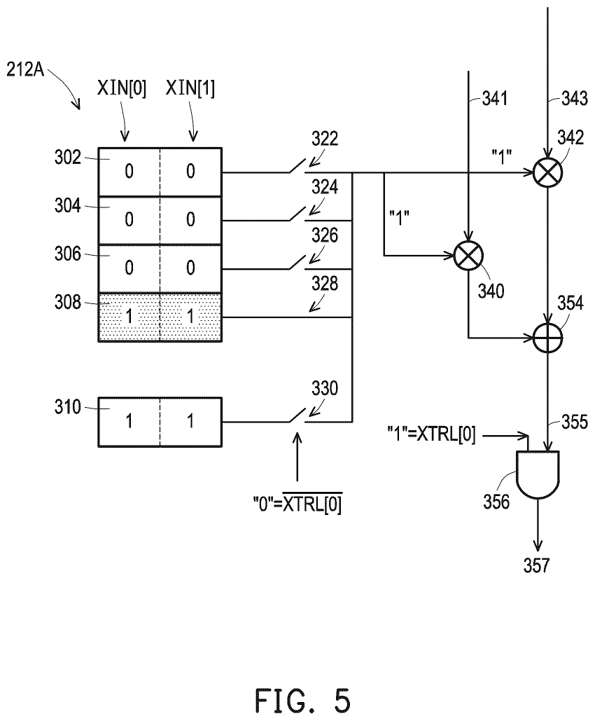

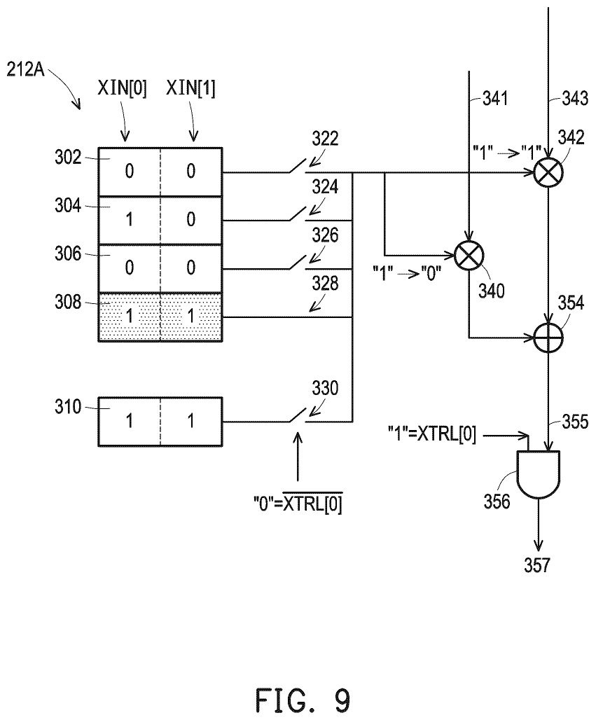

To further elaborate the method 400, FIGS. 5, 6, 7, 8, and 9 illustrate a non-limiting example for one of the macros 212 of the CiM system 200 (e.g., macro 212A) to output a number of MAC values for a first input signal, XIN[0] (e.g., a first data word) and a second input signal, XIN[1] (e.g., a second data word), in a certain CiM operation. In this illustrative example, the first and second input signals, XIN[0] and XIN[1], each have a number of bits (e.g., 4 bits). For instance, as obtained or received in a current CiM operation, XIN[0]=“0101” and XIN[1]=“0001,” and in a previous CiM operation, XIN[0]=“0001” and XIN[1]=“0001.” Further, the macros 212A is configured to selectively calculate the MAC values of the first and second input signals, following the order of the values of respective bits of the first and second input signals (e.g., from the MSBs to LSBs).

Referring first to FIG. 5, in the previous CiM operation, XIN[0]=“0001” and XIN[1] =“0001,” bits of which are stored in the input storage components 302 to 308, respectively. For example, the input storage component 302 stores the MSBs of XIN[0] and XIN[1], “00,” and the input storage component 308 stores the LSBs of XIN[0] and XIN[1], “11.” In a last cycle of the previous CiM operation, as at least one of the bits of XIN[0] and XIN[1] is not equal to “0,” the control signal XTRL[0] is “1” through OR'ing “11.” Consequently, the switch 328 is turned on (as originally scheduled), and the switch 330 is turned off through logically inversing XTRL[0]. As such, the macro 212A can update the backup storage component 310 to be the same as the LSBs of XIN[0] and XIN[1], “11,” calculate the intermediate MAC value 355 through the multipliers 340-342 and the adder 354, and ADD the intermediate MAC value 355 and XTRL[0] as the final MAC value 357.

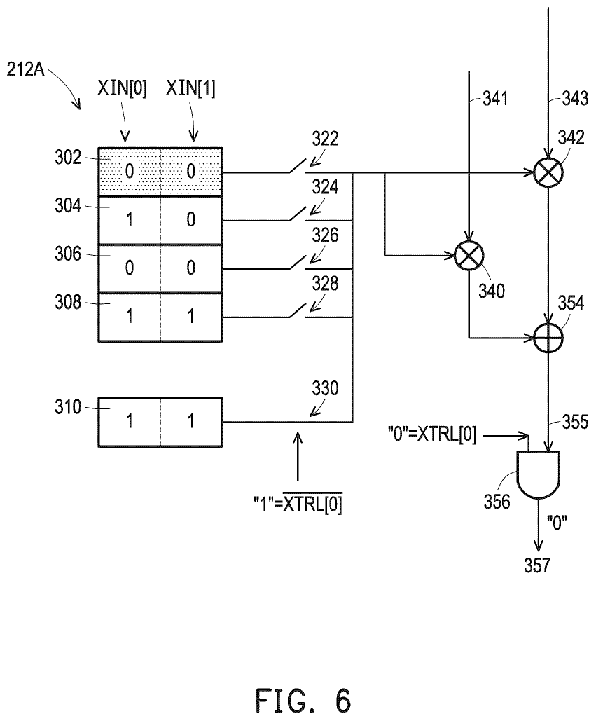

Referring next to FIG. 6, in the current CiM operation, XIN[0]=“0101” and XIN[1] =“0001,” bits of which are stored in the input storage components 302 to 308, respectively. For example, the input storage component 302 stores the MSBs of XIN[0] and XIN[1], “00,” and the input storage component 308 stores the LSBs of XIN[0] and XIN[1], “11.” In a first cycle of the current CiM operation, as both of the bits of XIN[0] and XIN[1] are equal to “0,” the control signal XTRL[0] is “0” through OR'ing “00.” Consequently, the switch 330 is turned on through logically inversing XTRL[0]. As such, the macro 212A can skip toggling the switch 322 and skip calculating the intermediate MAC value 355 through the multipliers 340-342 and the adder 354. Consequently, the macro 212A can directly output the final MAC value 357 as a fixed logic value, “0,” by AND'ing “0” of XTRL[0] with the non-computed intermediate MAC value 355.

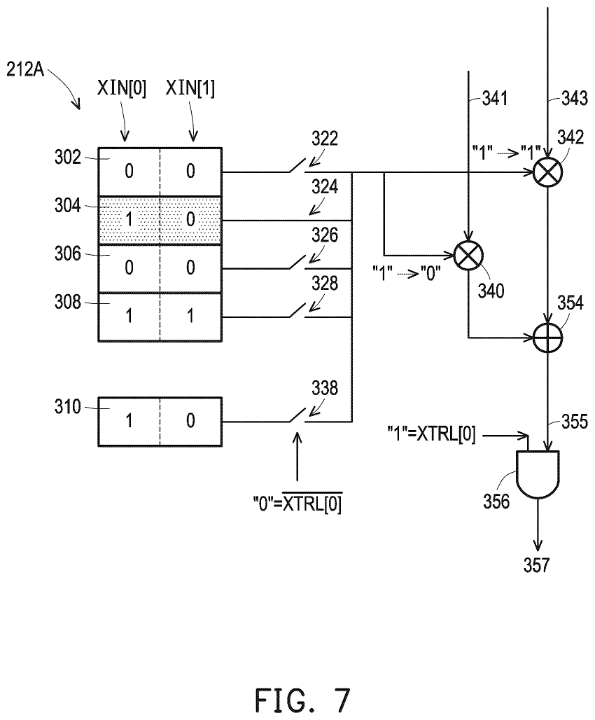

Referring next to FIG. 7, in a second cycle of the current CiM operation, as at least one of the bits of XIN[0] and XIN[1] is not equal to “0,” the control signal XTRL[0] is “1” through OR'ing “10.” Consequently, the switch 324 is turned on (as originally scheduled), and the switch 330 is turned off through logically inversing XTRL[0]. As such, the macro 212A can update the backup storage component 310 to be the same as the bits of XIN[0] and XIN[1] stored in the input storage component 304, “10,” calculate the intermediate MAC value 355 through the multipliers 340-342 and the adder 354, and ADD the intermediate MAC value 355 and XTRL[0] as the final MAC value 357.

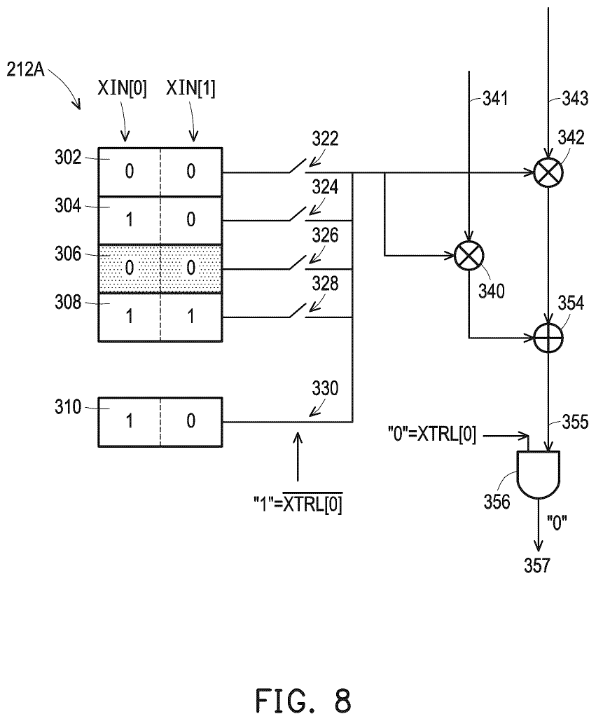

Referring next to FIG. 8, in a third cycle of the current CiM operation, as both of the bits of XIN[0] and XIN[1] are equal to “0,” the control signal XTRL[0] is “0” through OR'ing “00.” Consequently, the switch 330 is turned on through logically inversing XTRL[0]. As such, the macro 212A can skip toggling the switch 322 and skip calculating the intermediate MAC value 355 through the multipliers 340-342 and the adder 354. Consequently, the macro 212A can directly output the final MAC value 357 as a fixed logic value, “0,” by AND'ing “0” of XTRL[0] with the non-computed intermediate MAC value 355. It should be noted that the macro 212A may not update the backup storage component 310 when not actually performing MAC computation, in some embodiments. Thus, after the third cycle, the backup storage component 310 may still store the bits obtained in the second cycle, “10.”

Referring then to FIG, 9, in the fourth cycle of the current CiM operation, as at least one of the bits of XIN[0] and XIN[1] is not equal to “0,” the control signal XTRL[0] is “1” through OR'ing “11.” Consequently, the switch 328 is turned on (as originally scheduled), and the switch 330 is turned off through logically inversing XTRL[0]. As such, the macro 212A can update the backup storage component 310 to be the same as the bits of XIN[0] and XIN[1] stored in the input storage component 308, “11,” calculate the intermediate MAC value 355 through the multipliers 340-342 and the adder 354, and ADD the intermediate MAC value 355 and XTRL[0] as the final MAC value 357.

In one aspect of the present disclosure, an integrated circuit is disclosed. The integrated circuit includes a first logic gate configured to receive a first input signal and a second input signal, and generate a first control signal based on a first bit of first input signal and a first bit of the second input signal obtained in a current cycle. The integrated circuit includes a first backup storage component configured to store a second bit of the first input signal and a second bit of the second input signal obtained in a previous cycle. The integrated circuit includes a plurality of first macros each configured to selectively compute, based on the first control signal, a first multiply-accumulate (MAC) value for the first bit of the first input signal and the first bit of the second input signal.

In another aspect of the present disclosure, an integrated circuit is disclosed. The integrated circuit includes an array comprising a plurality of macros. Each macro is configured to output a plurality of multiply-accumulate (MAC) values of a first input signal and a second input signal in respectively different cycles. Each macro is configured to determine a first one of the plurality of MAC values in a current one of the cycles as either a fixed logic value or being computed based on a first bit of the first input signal and a first bit of the second input signal obtained in the current cycle.

In yet another aspect of the present disclosure, a method for operating a CiM system is disclosed. The method includes receiving a first input signal and a second input signal. The method includes in response to determining that at least one of a first bit of the first input signal or a first bit of the second input signal obtained in a current cycle is not equal to a first logic value, computing a multiply-accumulate (MAC) value of the first bit of the first input signal and the first bit of the second input signal. The method includes in response to determining that the first bit of the first input signal and the first bit of the second input signal obtained in the current cycle are each equal to the first logic value, outputting the MAC value as the first logic value.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first OR logic gate configured to:
receive a first input signal and a second input signal; and
generate a first control signal based on a first bit of first input signal and a first bit of the second input signal obtained in a current cycle;
a first backup storage component configured to store a second bit of the first input signal and a second bit of the second input signal obtained in a previous cycle; and
a first macro configured to selectively compute, based on the first control signal, a first multiply-accumulate (MAC) value for the first bit of the first input signal and the first bit of the second input signal.

2. The integrated circuit of claim 1, wherein the first macro is further configured to output the first MAC value, based on the first control signal, as either a fixed logic value or being computed based on the first bit of the first input signal and the first bit of the second input signal.

3. The integrated circuit of claim 1, wherein the first macro comprises an AND logic gate configured to output the first MAC value based on a logic inverse of the first control signal.

4. The integrated circuit of claim 1, wherein the first bit of the first input signal has a larger value than the second bit of the first input signal, and the first bit of the second input signal has a larger value than the second bit of the second input signal.

5. The integrated circuit of claim 1, wherein the first macro comprises:
a memory array;
a first multiplier operatively coupled to a first bit cell of the memory array;
a second multiplier operatively coupled to a second bit cell of the memory array; and
an adder operatively coupled to the first and second multipliers.

6. The integrated circuit of claim 5, wherein in response to determining that a logic inverse of the first control signal is equal to a first logic value, the first multiplier remains coupled to the first backup storage component, and the second multiplier remains coupled to the first backup storage component.

7. The integrated circuit of claim 6, wherein in response to determining that a logic inverse of the first control signal is equal to a second logic value, the first multiplier toggles to receive the first bit of the first input signal obtained in the current cycle, and the second multiplier toggles to receive the first bit of the second input signal obtained in the current cycle.

8. The integrated circuit of claim 1, further comprising:
a second OR logic gate configured to:
receive a third input signal and a fourth input signal; and
generate a second control signal based on a first bit of third input signal and a first bit of the fourth input signal in the current cycle;
a second backup storage component configured to store a second bit of the third input signal and a second bit of the fourth input signal in the previous cycle; and
a second macro configured to selectively compute, based on the second control signal, a second MAC value of the first bit of the third input signal and the first bit of the fourth input signal.

9. The integrated circuit of claim 8, further comprising:
a plurality of the first macros; and
a plurality of second macros.

10. The integrated circuit of claim 9, wherein the plurality of first macros and the plurality of second macros form a first column and a second column of a CiM (Compute-in-Memory) array, respectively.

11. An integrated circuit, comprising:
a first logic gate configured to:
receive a first input signal and a second input signal; and
generate a first control signal by OR'ing a first bit of first input signal and a first bit of the second input signal that are obtained in a current cycle; and
a macro configured to receive the first controls signal, and selectively compute, based on the first control signal, a first multiply-accumulate (MAC) value for the first bit of the first input signal and the first bit of the second input signal.

12. The integrated circuit of claim 11, further comprising:
a first backup storage component configured to store a second bit of the first input signal and a second bit of the second input signal that were obtained in a previous cycle.

13. The integrated circuit of claim 12, wherein the macro comprises:
a memory array;
a first multiplier operatively coupled to a first bit cell of the memory array;
a second multiplier operatively coupled to a second bit cell of the memory array; and
an adder operatively coupled to the first and second multipliers.

14. The integrated circuit of claim 13, wherein in response to determining that a logic inverse of the first control signal is equal to a first logic value, the first multiplier remains coupled to the first backup storage component, and the second multiplier remains coupled to the first backup storage component.

15. The integrated circuit of claim 14, wherein in response to determining that a logic inverse of the first control signal is equal to a second logic value, the first multiplier toggles to receive the first bit of the first input signal obtained in the current cycle, and the second multiplier toggles to receive the first bit of the second input signal obtained in the current cycle.

16. The integrated circuit of claim 11, wherein the macro comprises an AND logic gate configured to output the first MAC value according to a first input and a second input, the first input being equal to a logic inverse of the first control signal, the second input being equal to a sum of the first bit of the first input signal multiplied by a first weight and the first bit of the second input signal multiplied by a second weight.

17. An integrated circuit, comprising:
a plurality of OR logic gates, each of the plurality of OR logic gates configured to:
receive a first input signal and a second input signal; and
generate a control signal based on a first bit of first input signal and a first bit of the second input signal that are obtained in a current cycle; and
a CiM (Compute-in-Memory) array comprising a plurality of columns, each of the plurality of columns operatively coupled to a corresponding one of the plurality of OR logic gates and comprising a plurality of macros;
wherein each of the plurality of macros is configured to selectively compute, based on the control signal, a multiply-accumulate (MAC) value for the first bit of the first input signal and the first bit of the second input signal.

18. The integrated circuit of claim 17, further comprising:
a plurality of backup storage components, each of the plurality of backup storage components is operatively coupled to a corresponding one of the macros and configured to store a second bit of the first input signal and a second bit of the second input signal that were obtained in a previous cycle.

19. The integrated circuit of claim 17, wherein each of the macros comprises:
a memory array;
a first multiplier operatively coupled to a first bit cell of the memory array and configured to receive the first input signal;
a second multiplier operatively coupled to a second bit cell of the memory array and configured to receive the second input signal; and
an adder operatively coupled to the first and second multipliers.

20. The integrated circuit of claim 17, wherein the macros each comprise an AND logic gate configured to output the MAC value based on a logic inverse of the control signal.
